(19) United States
(12) Patent Application Publication
(10) Pub. No.: US 2006/0221028 A1
(43) Pub. Date: Oct. 5, 2006

(54) Display, array substrate and method of driving display

(76) Inventor: Yoshiro Aoki, Kitamoto-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/386,750

(22) Filed: Mar. 23, 2006

(30) Foreign Application Priority Data
Mar. 31, 2005 (JP) 2005-104649

(51) Int. Cl. G09G 3/36

(52) U.S. Cl. 345/88

(57) ABSTRACT

Each pixel includes a drive control element which includes a control terminal, a first terminal connected to a first power supply terminal, and a second terminal outputting a current having a magnitude corresponding to a voltage between the control terminal and the first terminal, a display element which includes a pixel electrode, a counter electrode connected to a second power supply terminal, and an active layer interposed between the pixel electrode and the counter electrode, a switch connected between the second terminal and the pixel electrode, a first capacitor connected between the control terminal and a constant-potential terminal, a second capacitor, a switch connected in series with the second capacitor between the control terminal and a video signal line, a switch connected between the second terminal and an electrode of the second capacitor, and a switch connected between the second terminal and another electrode of the second capacitor.

### CROSS-REFERENCE TO RELATED APPLICATIONS

This application is based upon and claims the benefit of priority from prior Japanese Patent Application Ser. No. 2005-104649, filed Mar. 31, 2005, the entire contents of which are incorporated herein by reference.

### BACKGROUND OF THE INVENTION

1. Field of the Invention

The present invention relates to a display, an array substrate, and a method of driving a display.

2. Description of the Related Art

In a display such as an organic electroluminescent (EL) display which controls the optical characteristics of each display element by a magnitude of a drive current passed through the display element, image quality deterioration such as luminance unevenness occurs if magnitudes of the drive currents vary. Therefore, when an active matrix driving method is used in this display, the characteristics of a drive control element for controlling the magnitude of the drive current must be substantially the same between pixels. In this display, however, the drive control element is normally formed on an insulator such as a glass substrate, so the characteristics of the element easily vary.

U.S. Pat. No. 6,373,454 describes an organic EL display using a current mirror circuit in a pixel.

This pixel includes an n-channel field-effect transistor as the drive control element, an organic EL element, and a capacitor.

The source of the drive control element is connected to a power supply line at a low electric potential, and the capacitor is connected between the gate of the drive control element and the power supply line. The anode of the organic EL element is connected to a power supply line at a higher electric potential.

The pixel circuit is driven as described below.

First, the drain of the n-channel field-effect transistor is connected to its gate. A current I_{sig} with a magnitude corresponding to a video signal is made to flow between the drain and source of the n-channel field-effect transistor. This operation sets the voltage between electrodes of the capacitor, equal to a gate-to-source voltage necessary for the n-channel field-effect transistor to pass the current I_{sig} through its channel.

Then, the drain of the n-channel field-effect transistor is disconnected from its gate, and the voltage between the electrodes of the capacitor is maintained. The drain of the n-channel field-effect transistor is subsequently connected to the cathode of the organic EL element. This allows a drive current I_{drv} with a magnitude almost equal to that of the current I_{sig} to flow through the organic EL element. The organic EL element emits light at a luminance corresponding to the magnitude of the drive current I_{drv}.

The above configuration makes it possible for the drive current I_{drv} which flows between the drain and source of the n-channel field-effect transistor during a retention period following a write period, to have a magnitude almost equal to a magnitude of the current I_{sig} supplied as a video signal during the write period. Therefore, the influence of not only a threshold value Vₜₕ but also the mobility, dimensions, and the like of the n-channel field-effect transistor on the drive current I_{drv} can be eliminated.

However, it is difficult for the above display to write the video signal I_{sig} when a magnitude of the drive current I_{drv} corresponds to the video signal I_{sig} is small. Therefore, the display unevenness easily occurs when an image of a low gray level is displayed.

### BRIEF SUMMARY OF THE INVENTION

According to a first aspect of the present invention, there is provided a display comprising pixels and video signal lines arranged correspondently with columns which the pixels form, wherein each of the pixels comprises a drive control element which includes a control terminal, a first terminal connected to a first power supply terminal, and a second terminal outputting a current having a magnitude corresponding to a voltage between the control terminal and the first terminal, a display element which includes a pixel electrode, a counter electrode connected to a second power supply terminal, and an active layer interposed between the pixel electrode and the counter electrode, an output control switch connected between the second terminal and the pixel electrode, a first capacitor connected between the control terminal and a constant-potential terminal, a second capacitor, a signal supply control switch, the second capacitor and the signal supply control switch being connected in series between the control terminal and the video signal line, a first diode-connecting switch connected between the second terminal and an electrode of the second capacitor, and a second diode-connecting switch connected between the second terminal and another electrode of the second capacitor.

According to a second aspect of the present invention, there is provided a display comprising pixels and video signal lines arranged correspondently with columns which the pixels form, wherein each of the pixels comprises a drive control element which includes a control terminal, a first terminal connected to a first power supply terminal, and a second terminal outputting a current having a magnitude corresponding to a voltage between the control terminal and the first terminal, a display element which includes a pixel electrode, a counter electrode connected to a second power supply terminal, and an active layer interposed between the pixel electrode and the counter electrode, an output control switch connected between the second terminal and the pixel electrode, a first capacitor connected between the control terminal and a constant-potential terminal, a second capacitor, and a switch group switching a connection state among first and third states, the first state being a state that the second terminal is connected to the control terminal and disconnected from the video signal line, the second state being a state that the second terminal is connected to the control terminal via the second capacitor and connected to the video signal line, and the third state being a state that the second terminal, the control terminal and the video signal line are disconnected from one another.

According to a third aspect of the present invention, there is provided an array substrate comprising pixel circuits and video signal lines arranged correspondently with columns which the pixel circuits form, wherein each of the pixel circuits comprises a drive control element which includes a control terminal, a first terminal connected to a power supply terminal, and a second terminal outputting a current having a magnitude corresponding to a voltage between the control terminal and the first terminal, a pixel electrode, an output control switch connected between the second terminal and the pixel electrode, a first capacitor connected between the control terminal and a constant-potential terminal, a second capacitor, a signal supply control switch, the second capacitor and the signal supply control switch being connected in series between the control terminal and the video signal line, a first diode-connecting switch connected between the second terminal and an electrode of the second capacitor, and a second diode-connecting switch connected between the second terminal and another electrode of the second capacitor.

According to a fourth aspect of the present invention, there is provided an array substrate comprising pixel circuits and video signal lines arranged correspondently with columns which the pixel circuits form, wherein each of the pixel circuits comprises a drive control element which includes a control terminal, a first terminal connected to a power supply terminal, and a second terminal outputting a current having a magnitude corresponding to a voltage between the control terminal and the first terminal, a pixel electrode, an output control switch connected between the second terminal and the pixel electrode, a first capacitor connected between the control terminal and a constant-potential terminal, a second capacitor, and a switch group switching a connection state among first and third states, the first state being a state that the second terminal is connected to the control terminal and disconnected from the video signal line, the second state being a state that the second terminal is connected to the control terminal via the second capacitor and connected to the video signal line, and the third state being a state that the second terminal, the control terminal and the video signal line are disconnected from one another.

According to a fifth aspect of the present invention, there is provided a method of driving a display comprising pixels and video signal lines arranged correspondently with columns which the pixels form, each of the pixels comprising a drive control element which includes a control terminal, a first terminal connected to a first power supply terminal, and a second terminal outputting a current having a magnitude corresponding to a voltage between the control terminal and the first terminal, a display element which includes a pixel electrode, a counter electrode connected to a second power supply terminal, and an active layer interposed between the pixel electrode and the counter electrode, an output control switch connected between the second terminal and the pixel electrode, a first capacitor connected between the control terminal and a constant-potential terminal, and a second capacitor, comprising executing a reset operation, a write operation, and a display operation in this order, wherein the reset operation includes disconnecting the pixel electrode from the second terminal, connecting the second terminal to the control terminal, and thereafter, disconnecting the second terminal from the control terminal, wherein the write operation includes connecting the second terminal to the video signal line, connecting the second terminal to the control terminal via the second capacitor, passing a write current as a video signal between the first power supply terminal and the video signal line, and thereafter, disconnecting the control terminal from the second terminal and the video signal line, and wherein the display operation includes connecting the second terminal to the pixel electrode.

### BRIEF DESCRIPTION OF THE SEVERAL VIEWS OF THE DRAWING

FIG. 1 is a plan view schematically showing a display according to a first embodiment of the present invention;

FIG. 2 is a partial sectional view schematically showing an example of a structure that can be adopted for the display shown in FIG. 1;

FIG. 3 is an equivalent circuit diagram showing a pixel included in the display shown in FIG. 1;

FIG. 4 is a timing chart schematically showing an example of a method of driving the display shown in FIG. 1;

FIG. 5 is an equivalent circuit diagram of a pixel included in a display according to a variation;

FIG. 6 is an equivalent circuit diagram of a pixel included in a display according to another variation;

FIG. 7 is a plan view schematically showing a display in according to a second embodiment of the present invention;

FIG. 8 is an equivalent circuit diagram of a pixel included in the display shown in FIG. 7; and

FIG. 9 a timing chart schematically showing an example of a method of driving the display shown in FIG. 7.

### DETAILED DESCRIPTION OF THE INVENTION

Embodiments of the present invention will be described below in detail with reference to the drawings. In the drawings, components having similar functions are denoted by the same reference numerals and duplicate descriptions will be omitted.

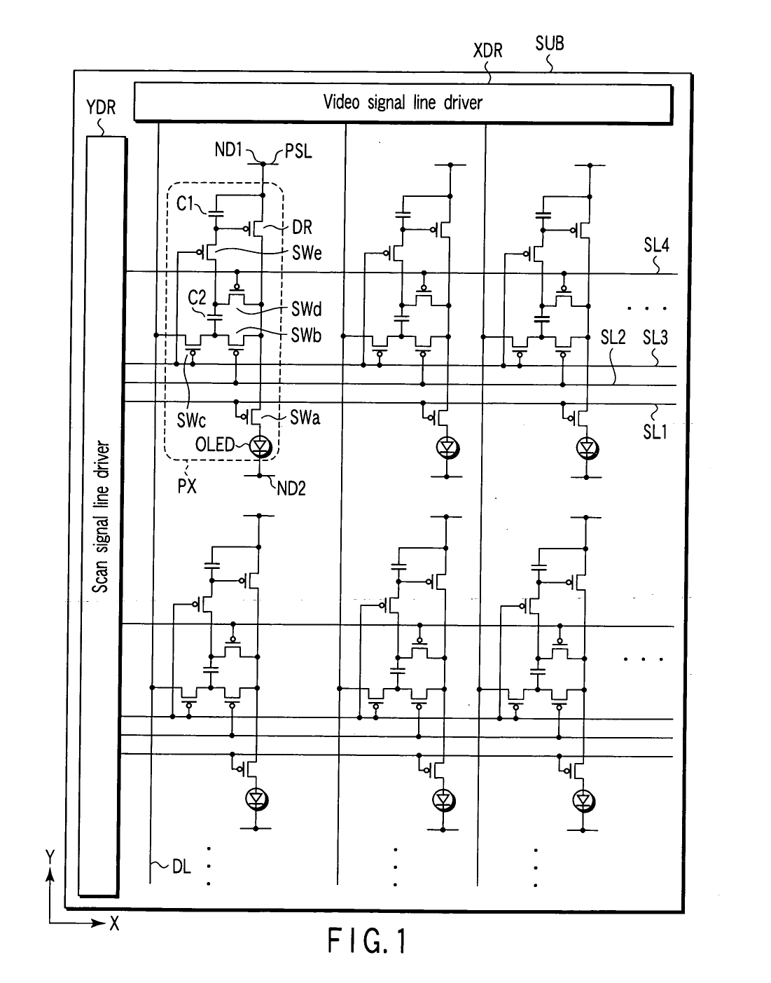

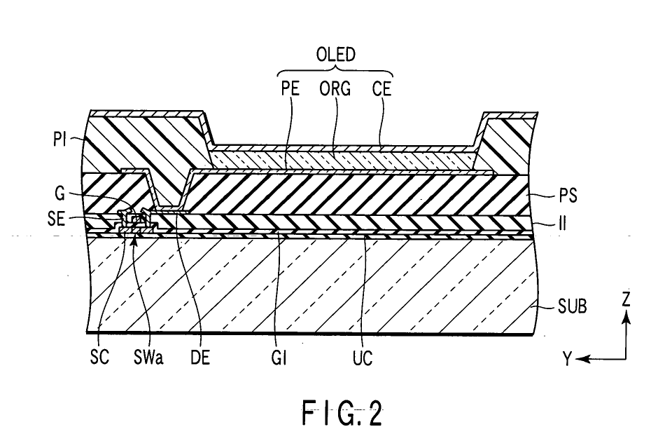

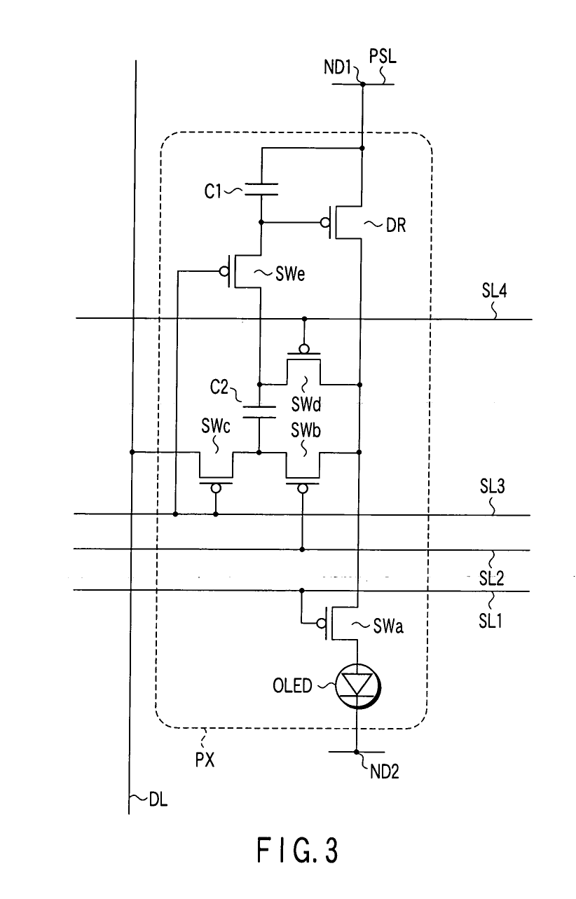

FIG. 1 is a plan view schematically showing a display according to a first embodiment of the present invention. FIG. 2 is a partial sectional view schematically showing an example of a-structure that can be adopted for the display shown in FIG. 1. FIG. 3 is an equivalent circuit diagram showing a pixel included in the display shown in FIG. 1. In FIG. 2, the display is drawn so that its display surface, that is, its front surface or light emitting surface faces the bottom of the drawing, while its back surface faces the top of the drawing.

This display is a bottom emission organic EL display which employs an active matrix driving method. The organic EL display includes an insulating substrate SUB such as a glass substrate.

For example, an SiNₓ layer and an SiOₓ layer are sequentially stacked on the substrate SUB as an undercoat layer UC shown in FIG. 2.

Semiconductor layers SC in each of which source and drain are formed, a gate insulator GI, and gates G are sequentially stacked on the undercoat layer UC. the semiconductor layers SC are, for example, polysilicon layers. The gate insulator GI can be formed using, for example, tetraethyl orthosilicate (TEOS). The gates G are made of, for example, MoW. The semiconductor layers SC, gate insulator GI, and gates G form top-gate type thin-film transistors. In this embodiment, these thin-film transistors are p-channel thin-film transistors utilized as drive control elements DR and switches SWa to SWe shown in FIGS. 1 and 3.

Bottom electrodes of capacitors C1 and C2 and scan signal lines SL1 to SL4 shown in FIG. 1 and 3 are further arranged on the gate insulator GI. The bottom electrodes and the scan signal lines SL1 to SL4 can be formed in the same step as that for the gate G.

As shown in FIG. 1, the scan signal lines SL1 to SL4 extend along the rows of the pixels PX, i.e., in an X direction, and are arranged in a Y direction along the columns of the pixels PX. The scan signal lines SL1 to SL4 are connected to a scan signal line driver YDR.

An interlayer insulating film II shown in FIG. 2 covers the gate insulator GI, the gates G, the scan signal lines SL1 to SL4, and the bottom electrodes of the capacitors C1 and C2. Parts of the interlayer insulating film II are utilized as dielectric layers of the capacitors C1 and C2.

On the interlayer insulating film II, top electrodes of the capacitors C1 and C2 shown in FIGS. 1 and 3,source electrodes SE and drain electrodes DE shown in FIG. 2, and video signal lines DL and power supply lines PSL shown in FIGS. 1 and 3 are arranged. The top electrodes of the capacitors C1 and C2, source electrodes SE, drain electrodes DE, video signal lines DL, and power supply lines PSL can be formed in the same step and may have a three-layer structure of, for example, Mo, Al, and Mo.

The source electrodes SE and drain electrodes DE are electrically connected to sources and drains of the thin-film transistors via contact holes formed in the interlayer insulting film II.

As shown in FIG. 1, the video signal lines DL extend in the Y direction and are arranged in the X direction. The video signal lines DL are connected to a video signal line driver XDR.

The power supply lines PSL extend in the Y direction and are arranged in the X direction, for example.

A passivation film PS shown in FIG. 2 covers the source electrodes SE, drain electrodes DE, video signal lines DL, power supply lines PSL, and top electrodes of the capacitors C1 and C2. The passivation film PS is made of , for example, SiNₓ.

As shown in FIG. 2, light-transmissive first electrodes PE as front electrodes are arranged on the passivation film PS such that they are spaced apart from one another. Each of the first electrodes PE is a pixel electrode connected through a through-hole formed in the passivation film PS to the drain electrode DE to which the drain of the switch SWa is connected.

In this embodiment, the first electrode PE is an anode. A transparent conductive oxide, for example, indium tin oxide (ITO) can be used as a material of the first electrode PE.

A partition insulating layer PI shown in FIG. 2 is further placed on the passivation film PS. The partition insulating layer PI has through-holes formed at positions corresponding to the first electrodes PE or slits formed at positions corresponding to columns or rows formed by the first electrodes PE. Here, by way of example, the partition insulating layer PI has through-holes formed at positions corresponding to the first electrodes PE.

The partition insulating layer PI is, for example, an organic insulating layer. The partition insulating layer PI can be formed using, for example, a photolithography technique.

An organic layer ORG including an emitting layer is placed on each of the first electrodes PE as an active layer. The emitting layer is, for example, a thin film containing a luminescent organic compound that emits red, green, or blue light. In addition to the emitting layer, the organic layer ORG may include a hole injection layer, a hole transporting layer, a hole blocking layer, an electron transporting layer, and an electron injection layer.

The partition insulating layer PI and the organic layer ORG are covered with a second electrode CE as a counter electrode. The second electrode CE is a common electrode shared among the pixels PX. In this embodiment, the second electrode CE is a light-reflective cathode serving as a back electrode. For example, an electrode wire (not shown) is formed on the layer on which the video signal lines DL are formed, and the second electrode CE is electrically connected to the electrode wire via a contact hole formed in the passivation film PS and partition insulating layer PI. Each organic EL element OLED is composed of the first electrode PE, organic layer ORG, and second electrode CE.

A plurality of the pixels PX are arranged in a matrix on the insulating substrate SUB. Each of the pixels PX is placed near an intersection of the video signal line DL and scan signal line SL1.

Each pixel PX includes the organic EL element OLED as a display element, a drive circuit, and an output control switch SWa. In this embodiment, as shown in FIGS. 1 and 3, the drive circuit includes a drive control element DR, signal supply control switches SWc and SWe, diode-connecting switches SWb and SWd, and the capacitors C1 and C2. As described above, in this embodiment, the drive control circuit DR and switches SWa to SWe are p-channel thin-film transistors.

The drive circuit, the output control switch SWa, and the pixel electrode PE constitute a pixel circuit. The switches SWb and SWe constitute a switch group that switches the connection state of the video signal line DL and a drain and a gate of the drive control element DR, among a first state that the drain is connected to the gate and disconnected from the video signal line DL, a second state that the drain is connected to the gate via the capacitor C2 and to the video signal line DL, and a third state that the drain, gate, and video signal line DL are disconnected from one another.

The drive control element DR, the output control switch SWa, and the organic EL element OLED are connected in series in this order between a first power supply terminal ND1 and a second power supply terminal ND2. A gate of the switch SWa is connected to the scan signal line SL1. In this embodiment, the first power supply terminal ND1 is a high-potential power supply terminal connected to a power supply line PSL. The second power supply terminal ND2 is a low-potential power supply terminal.

The capacitor C1 is connected between a first constant-potential terminal and the gate of the drive control element DR. In this embodiment, the first constant-potential terminal is connected to the first power supply terminal ND1.

The signal supply control switch SWc, capacitor C2, and signal supply control switch SWe are connected in series in this order between the video signal line DL and the gate of the drive control element DR. Gates of the switches SWc and SWe are connected to a scan signal line SL3.

The diode-connecting switch SWb is connected between the drain of the drive control element DR and one electrode of the capacitor C2 on the side of the video signal line DL. The diode connection switch SWd is connected between the drain of the drive control element DR and the other electrode of the capacitor C2. A gate of the switch SWb is connected to the scan signal line SL2. A gate of the switch SWd is connected to a scan signal line SL4.

The video signal line driver XDR and the scan signal line driver YDR are further arranged on the insulating substrate SUB. The video signal line driver XDR includes a plurality of current sources and a plurality of constant-voltage sources correspondently with the video signal lines DL. Each of the current sources outputs a write current serving as a video signal, to the video signal line DL. Each of the constant-voltage sources outputs a constant voltage (reset voltage or potential) serving as a reset signal, to the video signal line DL.

Note that the organic EL display from which the organic layer ORG and the second electrode CE are omitted, the organic EL display from which the partition insulating film PI, the organic layer ORG and the second electrode CE are omitted, or the organic EL display from which not only the above components but also the video signal line driver XDR and/or the scan signal line driver YDR are omitted corresponds to an array substrate.

The organic EL display is driven by, for the example, the method described below.

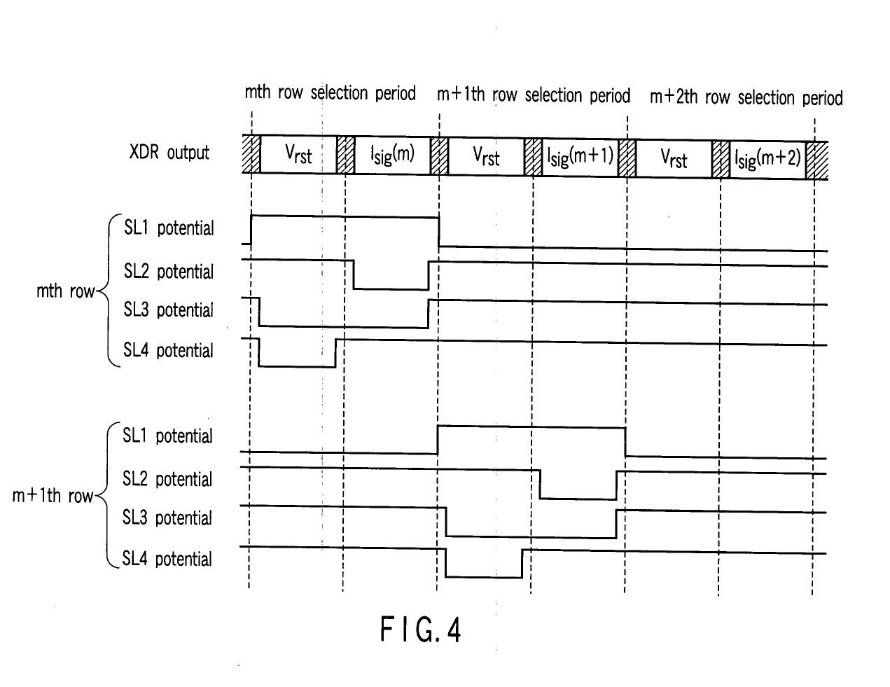

FIG. 4 is a timing chart schematically showing an example of a method of driving the display shown in FIG. 1. In the figure, the abscissa indicates time, while the ordinate indicates potential.

As for the “XDR output” in FIG. 4, during the period shown as “I_{sig}(m)”, the video signal line driver XDR outputs a video signal I_{sig}(m) to the video signal line DL. During the period shown as “Vᵣₛₜ”, the video signal line driver XDR outputs a reset signal Vᵣₛₜ to the video signal line DL. In FIG. 4, the waveforms shown as “SL1 potential” to “SL4 potential” represent the potentials of the scan signal lines SL1 to SL4, respectively.

With the method shown in FIG. 4, the display in FIG. 4 is driven in the manner described below.

When a certain gray level is to be displayed on one of the pixels PX in the m-th row, during a period in which the pixels PX in the m-th row are selected, that is, during an m-th row selection period, the switch SWa is opened (nonconductive state). During a period over which the switch SWa is open, a reset operation and write operation described below are sequentially executed.

In a reset period over which the reset operation is executed, the switches SWc to SWe are closed (conductive state) first. At the same time, the video signal line DL is connected to the constant-voltage source included in the video signal line driver XDR and the potential of the video signal line DL is set at the reset potential Vᵣₛₜ, while the switches SWa and SWb are kept open (nonconductive state). The reset potential Vᵣₛₜ is, for example, almost equal to the sum V_{dd} +Vₜₕ of the potential V_{dd} of the first power supply terminal ND1 and the threshold voltage Vₜₕ of the drive control element DR. After certain time period has elapsed, the switch SWd is opened so as to finish the reset period.

The reset operation sets the gate potential of the drive control element DR almost equal to the sum V_{dd} +Vₜₕ. The reset operation also sets the potential of the video signal line DL equal to the reset potential Vᵣₛₜ.

During a write period following the reset period, a write operation is executed. First, the switch SWb is closed. The switches SWa and SWd are kept open, while the switches SWc and SWe are kept closed. The video signal line DL is connected to the current source included in the video signal line driver XDR, which then outputs a video signal to the video signal line DL. That is, the write current I_{sig}(m) is made to flow from the first power supply terminal ND1 to the video signal line DL. After a certain time period has elapsed, the switches SWb, SWc, and SWe are opened so as to finish the write period.

The write operation sets the gate potential V_{g} of the drive control element DR almost equal to the sum V_{gs} +V_{dd} of the power supply potential V_{dd} and the gate-to-source voltage V_{gs} obtained when the drive control element DR passes the write current I_{sig}(m).

After the reset and write operations are executed, a display operation is started. That is, the switch SWa is closed. The m-th row selection period is finished by closing the switch SWa.

During a non-selection period or active display period over which the switch SWa is closed, the switches SWb to SWe remain open. A drive current I_{drv}(m) flows through the organic EL element OLED at a magnitude corresponding to the video signal I_{sig}(m). The organic EL element OLED emits light at a luminance corresponding to the magnitude of the drive current I_{drv}(m).

In the organic EL display described in U.S. Pat. No. 6,373,454, if, for example, pixels in the m-th row display a gray level within a high gray level range, the potential of the video signal line is set at a very low value when the m+1-th row selection period is started. Thus, to allow pixels in the m+1-th row to display a gray level within a low gray level range, it is necessary to greatly increase the potential of the video signal line by a write operation during the m+1-th row selection period. That is, the potential of the video signal line must be greatly changed in spite of the small magnitude of the write current I_{sig}(m+1). It is thus difficult to set the gate potential of the drive control element at a value corresponding to the write current I_{sig}(m+1) by the write operation during the m+1-th row selection period.

In contrast, the driving method described with reference to FIG. 4 executes a reset operation which sets the potential of the video signal line DL equal to the reset potential Vᵣₛₜ. When the reset potential Vᵣₛₜ is set at a sufficiently high value, it is unnecessary to greatly increase the potential of the video signal line DL by the write operation during the m+1-th row selection period in order to display a gray level within the low gray level range on the pixels PX in the m+1-th row, regardless of the gray level to be displayed on the pixels PX in the m-th row. Therefore, this driving method can prevent each gray level within the low gray level range from being displayed at a gray level higher than that to be displayed.

Further, the gate potential of the drive control element DR is almost equal to the sum V_{dd} +Vₜₕ when a reset operation is finished. Thus, even if the gate potential of the drive control element DR is not substantially changed by a write operation owing to the significantly small magnitude of the write current I_{sig}, the effect of the threshold voltage Vₜₕ on the drive current I_{drv} can be made almost equal among the pixels PX. This driving method, therefore, prevents the display unevenness from occurring when a low-gray-level image is displayed.

As described above, the driving method can prevent each gray level within the low gray level range from being displayed higher than that to be displayed. It can also prevent the display unevenness from occurring when a low-gray-level image is displayed. In addition, the driving method makes it possible to display gray levels within a middle gray level range and a high gray level range at a high reproducibility. That is, the driving method can display all the gray levels with a high reproducibility.

The present embodiment adopts the structure shown in FIG. 3 for the pixels PX. However, another structure can be adopted for the pixels PX.

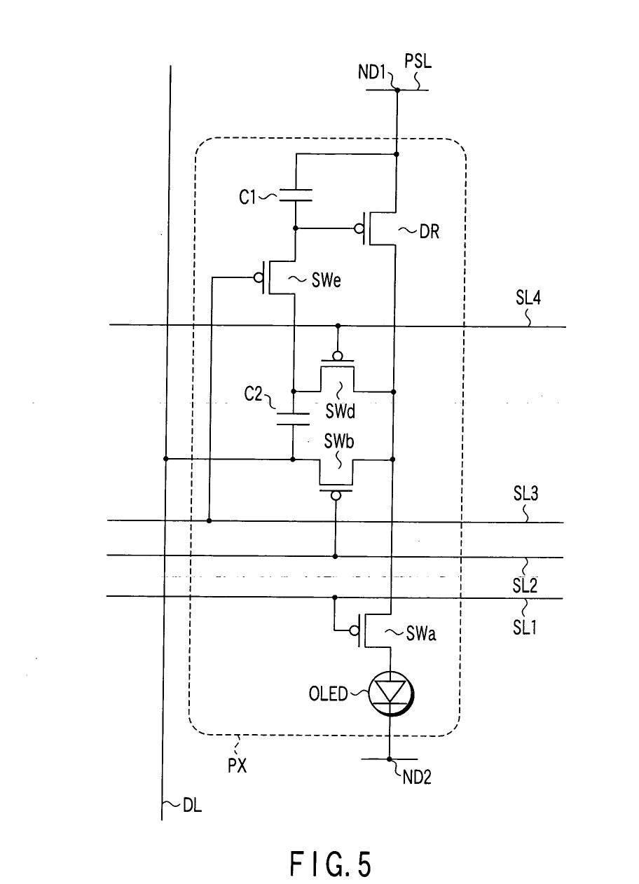

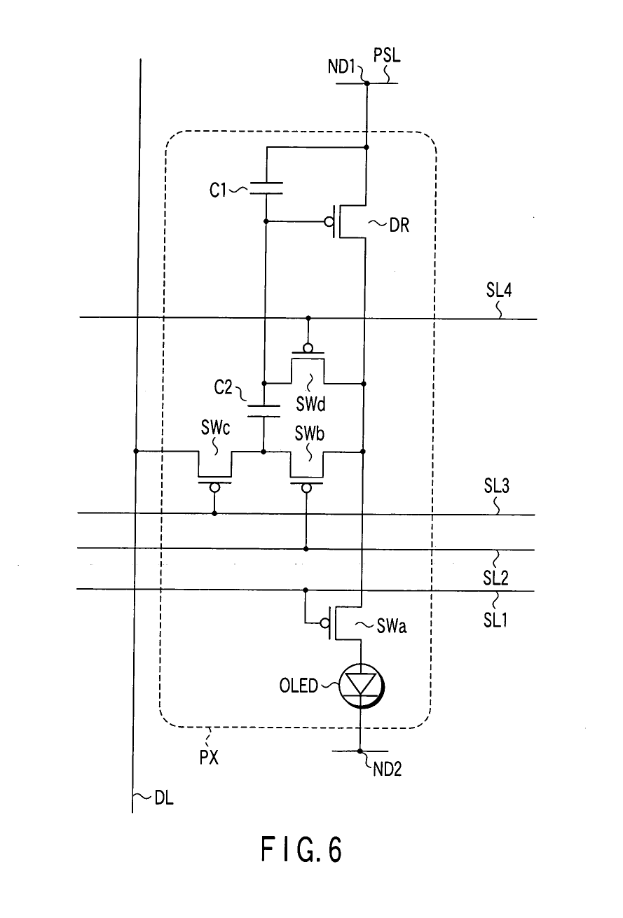

FIG. 5 is an equivalent circuit diagram of a pixel included in a display according to a variation. FIG. 6 is an equivalent circuit diagram of a pixel included in a display according to another variation.

The pixel PX in FIG. 5 has a structure similar to the structure of the pixel PX in FIG. 3 except that the switch SWc is omitted. The pixel PX in FIG. 6 has a structure similar to the structure of the pixel PX in FIG. 3 except that the switch SWe is omitted. Many variations may thus be made to the pixels PX.

The second embodiment of the present invention will be described below.

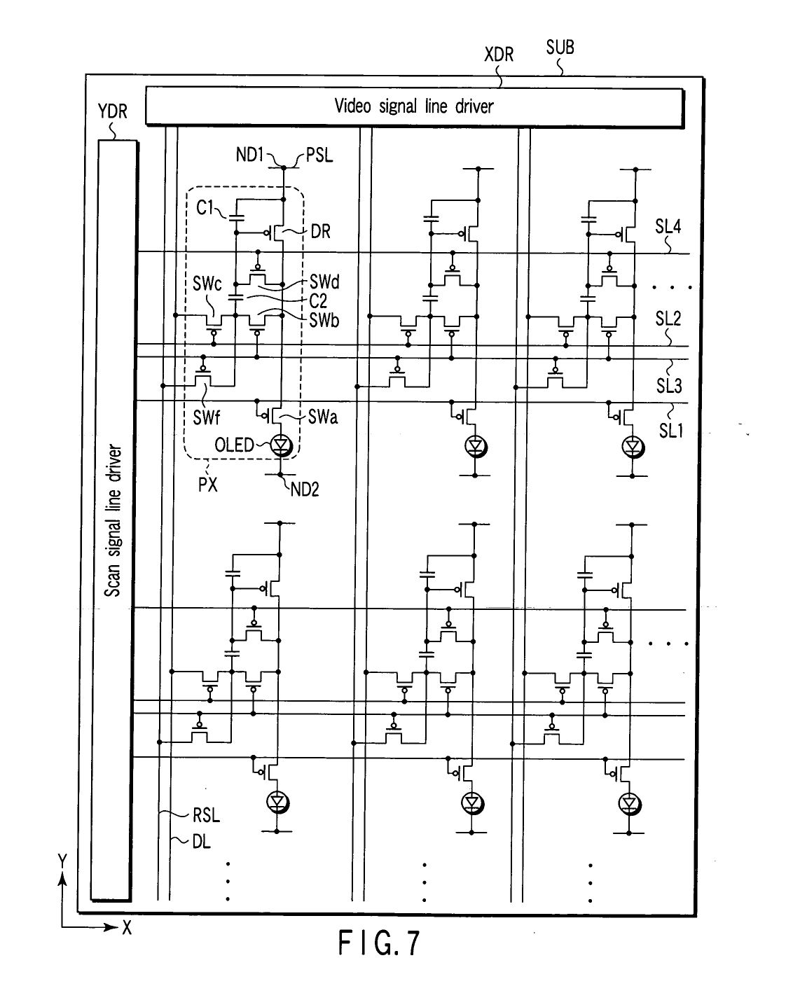

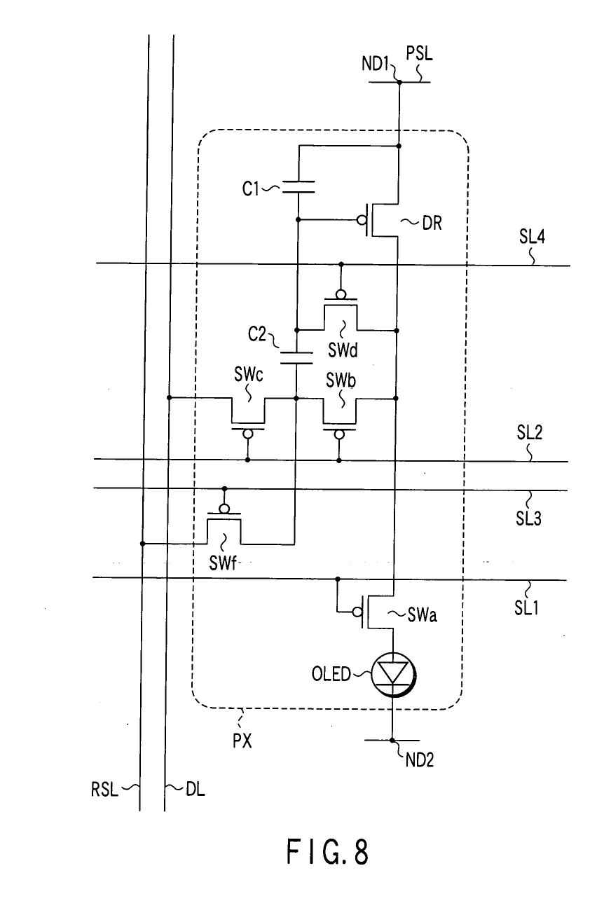

FIG. 7 is a plan view schematically showing a display in according to the second embodiment of the present invention. FIG. 8 is an equivalent circuit diagram of a pixel included in the display shown in FIG. 7.

The display is a bottom emission organic EL display which adopts the active matrix driving method. This organic EL display has a structure similar to that of the organic EL display shown in FIG. 1.

In this organic EL display, reset signal lines RSL are placed on the insulating substrate SUB. In this embodiment, as shown in FIG. 7, the reset signal lines RSL extend in the Y direction and are arranged in the X direction. In this embodiment, the reset signal lines RSL are connected to the video signal line driver XDR.

The switch SWe is omitted from each pixel PX. The gate of the switch SWb in each pixel is connected to the scan signal line SL2. A reset switch SWf is additionally placed in each pixel PX. The reset switch SWf is connected between the reset signal line RSL and the electrode of the capacitor C2 which is connected to the video signal line DL. A gate of the reset switch SWf is connected to the scan signal line SL3.

The organic EL display is driven by, for example, a method described below.

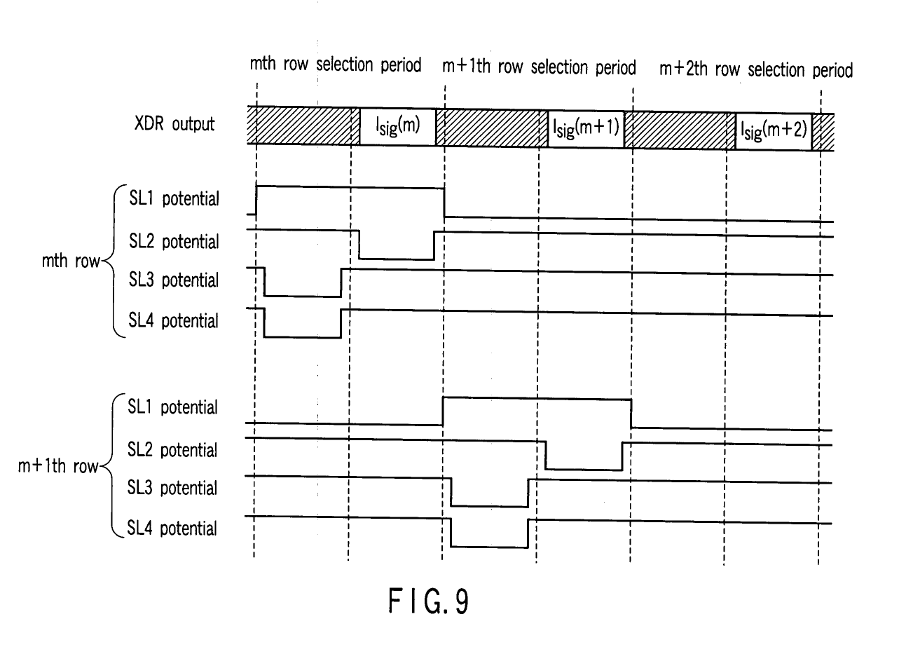

FIG. 9 a timing chart schematically showing an example of a method of driving the display shown in FIG. 7. In the figure, the abscissa indicates time, while the ordinate indicates potential.

As for the “XDR output” in FIG. 9, during the period shown as “I_{sig}(m)”, the video signal line driver XDR outputs a video signal I_{sig}(m) to the video signal line DL. In FIG. 9, the waveforms shown as “SL1 potential” to “SL4 potential” represent the potentials of the scan signal lines SL1 to SL4, respectively.

With the method shown in FIG. 9, the display in FIG. 7 is driven in the manner described below.

When a certain gray level is to be displayed on one of the pixels PX in the m-th row, during a period in which the pixels PX in the m-th row are selected, that is, during an m-th row selection period, the switch SWa is opened (nonconductive state). During a period over which the switch SWa is open, a reset operation and write operation described below are sequentially executed.

In a reset period over which the reset operation is executed, the switches SWd and SWf are closed (conductive state) first. The switches SWa to SWc are kept open (nonconductive state). For example, the potential of the reset signal line RSL is always set at the reset potential Vᵣₛₜ described above. After certain time period has elapsed, the switches SWd and SWf are opened so as to finish the reset period. The reset operation sets the gate potential of the drive control element DR almost equal to the sum V_{dd} +Vₜₕ.

During a write period following the reset period, a write operation is executed. First, the switches SWb and SWc are closed while the switches SWa, SWd and SWf are kept open. In this state, the video signal line driver XDR outputs a video signal to the video signal line DL. That is, the write current I_{sig}(m) is made to flow from the first power supply terminal ND1 to the video signal line DL. After a certain time period has elapsed, the switches SWb and SWc are opened so as to finish the write period. The write operation sets the gate potential V_{g} of the drive control element DR almost equal to the sum V_{gs} +V_{dd} of the power supply potential V_{dd} and the gate-to-source voltage V_{gs} obtained when the drive control element DR passes the write current I_{sig}(m).

After the reset and write operations are executed, a display operation is started. That is, the switch SWa is closed. The m-th row selection period is finished by closing the switch SWa.

During a non-selection period or active display period over which the switch SWa is closed, the switches SWb to SWd and SWf remain open. A drive current I_{drv}(m) flows through the organic EL element OLED at a magnitude corresponding to the video signal I_{sig}(m). The organic EL element OLED emits light at a luminance corresponding to the magnitude of the drive current I_{drv}(m).

As with the first embodiment, this driving method can make the effect of the threshold voltage Vₜₕ on the drive current I_{drv} almost equal among the pixels PX even if the gate potential of the drive control element DR hardly changes by the write operation due to a markedly small write current I_{sig}. This driving method, therefore, prevents the display unevenness from occurring when a low-gray-level image is displayed.

In the present embodiment, in contrast to the first embodiment, the reset signal lines RSL are provided separately from the video signal lines DL to supply reset signals to the pixels PX. This makes it possible to reduce the frequency of changes in the potential of each video signal line DL.

In the present embodiment, the scan signal lines SL3 may be omitted, with the gates of the switches SWf connected to the scan signal lines SL4. The reset signal lines RSL may be laid parallel to the scan signal lines SLl to SL4. Moreover, each pixel PX may include the switch SWe, which is omitted in the present embodiment.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A display comprising pixels and video signal lines arranged correspondently with columns which the pixels form, wherein each of the pixels comprises:
a drive control element which includes a control terminal, a first terminal connected to a first power supply terminal, and a second terminal outputting a current having a magnitude corresponding to a voltage between the control terminal and the first terminal;
a display element which includes a pixel electrode, a counter electrode connected to a second power supply terminal, and an active layer interposed between the pixel electrode and the counter electrode;
an output control switch connected between the second terminal and the pixel electrode;
a first capacitor connected between the control terminal and a constant-potential terminal;
a second capacitor;
a signal supply control switch, the second capacitor and the signal supply control switch being connected in series between the control terminal and the video signal line;
a first diode-connecting switch connected between the second terminal and an electrode of the second capacitor; and
a second diode-connecting switch connected between the second terminal and another electrode of the second capacitor.

2. The display according to claim 1, further comprising a reset signal line, wherein each of the pixels further comprises a reset switch connected between the reset signal line and the electrode of the second capacitor on a side of the video signal line.

3. The display according to claim 1, wherein the display element is an organic EL element.

4. A display comprising pixels and video signal lines arranged correspondently with columns which the pixels form, wherein each of the pixels comprises:
a drive control element which includes a control terminal, a first terminal connected to a first power supply terminal, and a second terminal outputting a current having a magnitude corresponding to a voltage between the control terminal and the first terminal;
a display element which includes a pixel electrode, a counter electrode connected to a second power supply terminal, and an active layer interposed between the pixel electrode and the counter electrode;
an output control switch connected between the second terminal and the pixel electrode;
a first capacitor connected between the control terminal and a constant-potential terminal;
a second capacitor; and
a switch group switching a connection state among first and third states, the first state being a state that the second terminal is connected to the control terminal and disconnected from the video signal line, the second state being a state that the second terminal is connected to the control terminal via the second capacitor and connected to the video signal line, and the third state being a state that the second terminal, the control terminal and the video signal line are disconnected from one another.

5. The display according to claim 4, further comprising a reset signal line, wherein each of the pixels further comprises a reset switch connected between the reset signal line and an electrode of the second capacitor on a side of the video signal line.

6. The display according to claim 4, wherein the display element is an organic EL element.

7. An array substrate comprising pixel circuits and video signal lines arranged correspondently with columns which the pixel circuits form, wherein each of the pixel circuits comprises:
a drive control element which includes a control terminal, a first terminal connected to a power supply terminal, and a second terminal outputting a current having a magnitude corresponding to a voltage between the control terminal and the first terminal;
a pixel electrode;
an output control switch connected between the second terminal and the pixel electrode;
a first capacitor connected between the control terminal and a constant-potential terminal;
a second capacitor;
a signal supply control switch, the second capacitor and the signal supply control switch being connected in series between the control terminal and the video signal line;
a first diode-connecting switch connected between the second terminal and an electrode of the second capacitor; and
a second diode-connecting switch connected between the second terminal and another electrode of the second capacitor.

8. The array substrate according to claim 7, further comprising a reset signal line, wherein each of the pixel circuits further comprises a reset switch connected between the reset signal line and the electrode of the second capacitor on a side of the video signal line.

9. An array substrate comprising pixel circuits and video signal lines arranged correspondently with columns which the pixel circuits form, wherein each of the pixel circuits comprises:
a drive control element which includes a control terminal, a first terminal connected to a power supply terminal, and a second terminal outputting a current having a magnitude corresponding to a voltage between the control terminal and the first terminal;
a pixel electrode;
an output control switch connected between the second terminal and the pixel electrode;
a first capacitor connected between the control terminal and a constant-potential terminal;
a second capacitor; and
a switch group switching a connection state among first and third states, the first state being a state that the second terminal is connected to the control terminal and disconnected from the video signal line, the second state being a state that the second terminal is connected to the control terminal via the second capacitor and connected to the video signal line, and the third state being a state that the second terminal, the control terminal and the video signal line are disconnected from one another.

10. The array substrate according to claim 9, further comprising a reset signal line, wherein each of the pixel circuits further comprises a reset switch connected between the reset signal line and an electrode of the second capacitor on a side of the video signal line.

11. A method of driving a display comprising pixels and video signal lines arranged correspondently with columns which the pixels form, each of the pixels comprising a drive control element which includes a control terminal, a first terminal connected to a first power supply terminal, and a second terminal outputting a current having a magnitude corresponding to a voltage between the control terminal and the first terminal, a display element which includes a pixel electrode, a counter electrode connected to a second power supply terminal, and an active layer interposed between the pixel electrode and the counter electrode, an output control switch connected between the second terminal and the pixel electrode, a first capacitor connected between the control terminal and a constant-potential terminal, and a second capacitor, comprising:
executing a reset operation, a write operation, and a display operation in this order,
wherein the reset operation includes disconnecting the pixel electrode from the second terminal, connecting the second terminal to the control terminal, and thereafter, disconnecting the second terminal from the control terminal,
wherein the write operation includes connecting the second terminal to the video signal line, connecting the second terminal to the control terminal via the second capacitor, passing a write current as a video signal between the first power supply terminal and the video signal line, and thereafter, disconnecting the control terminal from the second terminal and the video signal line, and
wherein the display operation includes connecting the second terminal to the pixel electrode.

12. The method according to claim 11, wherein during a period over which the second terminal is connected to the control terminal in the reset operation, an electrode of the second capacitor is connected to the control terminal while setting a potential of another electrode of the second capacitor at a reset potential.
